(19) United States
(12) Patent Application Publication
(10) Pub. No.: US 2026/0321326 A1
(43) Pub. Date: Oct. 15, 2026

(54) METHOD AND SYSTEM FOR OPTIMIZING READ REFERENCE VOLTAGES OF A THREE-DIMENSIONAL NAND FLASH MEMORY

(71) Applicant: Guangdong University of Technology, Guangzhou (CN)

(72) Inventors: Guojun HAN, Guangzhou (CN); Yanxun CHEN, Guangzhou (CN); Yang ZHANG, Guangzhou (CN); Zehao CHEN, Guangzhou (CN)

(21) Appl. No.: 19/663,316

(22) Filed: Apr. 30, 2026

(30) Foreign Application Priority Data
Jun. 17, 2025 (CN) 202510809014.6

(51) Int. Cl. G11C 16/34; G11C 16/26; G11C 16/30

(52) U.S. Cl. CPC G11C 16/349; G11C 16/26; G11C 16/30

(57) ABSTRACT

A method for optimizing read reference voltages of a three-dimensional NAND flash memory includes: obtaining a program/erase cycle count and a data retention time of the NAND flash memory; in response to determining that the data retention time is available, inputting the program/erase cycle count and the data retention time into a preset optimal read reference voltage prediction model to obtain an average optimal offset value for each read reference voltage; in response to determining that the data retention time is unavailable, estimating the data retention time using a sampling adjustment method, and inputting the estimated data retention time and the program/erase cycle count into the preset prediction model to obtain the average optimal offset value for each read reference voltage; and compensating the average optimal offset value using a layer-to-layer difference table to obtain an optimal read reference voltage value for each read reference voltage.

### CROSS-REFERENCE TO RELATED APPLICATIONS

This application claims the benefit of priority from Chinese Patent Application No. 202510809014.6, filed on Jun. 17, 2025. The content of the aforementioned application, including any intervening amendments thereto, is incorporated herein by reference in its entirety.

### TECHNICAL FIELD

This application relates to the field of semiconductor memory technologies, and more particularly, to a method and a system for optimizing read reference voltages of a three-dimensional NAND flash memory.

### BACKGROUND

With the rapid development of electronic information technology and the digital economy, the demand for data storage continues to grow. NAND flash memory has become a mainstream storage medium due to its non-volatility, high read/write performance, and low power consumption.

At present, NAND flash memory architectures have evolved from two-dimensional structures to three-dimensional structures with an increasing number of stacked layers. However, while the three-dimensional NAND flash memory improves storage density, it also introduces reliability challenges. On the one hand, significant variations exist among different layers. In a case where a uniform read reference voltage is applied during read operations, raw bit error rates (RBERs) may vary significantly across layers. On the other hand, multi-level cell techniques compress the threshold voltage distribution window, resulting in increased susceptibility of threshold voltage distributions to interference, which may lead to distribution overlap and boundary crossing, and consequently increase error rates and reduce reliability. To ensure data reliability, error correction codes (ECC) and read retry mechanisms are typically employed. However, as the program/erase cycle count increases, the data retention time extends, and various interference effects accumulate, the error rate rises, and the time required for error correction and read retry operations increases significantly. Therefore, a read reference voltage that minimizes the error rate corresponds to an optimal read reference voltage value, and how to efficiently predict the optimal read reference voltage value has become a key research focus.

Existing approaches for predicting an optimal read reference voltage value generally fall into two categories. One approach is a characteristic modeling method, in which a prediction model is established based on physical characteristics of the flash memory. However, such prediction models typically rely on multiple precise parameters, such as program/erase cycle count, temperature, and data retention time. After a power-off event, certain parameters, such as the data retention time, may be unavailable or inaccurate, thereby reducing prediction accuracy. Another approach is a sampling-based optimization method, in which multiple samplings are performed within a voltage range to fit an error rate curve and determine the optimal read reference voltage value. Although the sampling-based optimization method does not rely on prior parameter information, it incurs relatively high sampling overhead. In particular, for three-dimensional NAND flash memory, performing sampling across multiple layers may significantly increase time consumption. Accordingly, improving the prediction accuracy of a read reference voltage optimization strategy while reducing time overhead and ensuring read performance has become an important technical problem to be solved.

### SUMMARY

In order to address the problems that existing read reference voltage optimization strategies suffer from insufficient prediction accuracy and high time overhead, thereby adversely affecting read performance, the present disclosure provides a method for optimizing read reference voltages of a three-dimensional NAND flash memory, which can improve prediction accuracy of the read reference voltage optimization strategy, reduce time overhead, and enhance read performance.

To achieve the above technical effects, the present disclosure provides the following technical solutions.

A method for optimizing read reference voltages of a three-dimensional NAND flash memory, the method comprising:
(S1) obtaining a program/erase cycle count and a data retention time of the three-dimensional NAND flash memory;
(S2) determining whether the data retention time is available;
(S3) in response to determining that the data retention time is available, inputting the program/erase cycle count and the data retention time into a preset optimal read reference voltage prediction model to obtain an average optimal offset value for each read reference voltage of a plurality of read reference voltages;
(S4) in response to determining that the data retention time is unavailable, estimating the data retention time using a sampling adjustment method, and inputting the estimated data retention time and the program/erase cycle count into the preset optimal read reference voltage prediction model to obtain the average optimal offset value for each read reference voltage of the plurality of read reference voltages; and
(S5) compensating the average optimal offset value for each read reference voltage of the plurality of read reference voltages using a layer-to-layer difference table to obtain an optimal read reference voltage value for each read reference voltage of the plurality of read reference voltages of a respective layer of a plurality of layers of the three-dimensional NAND flash memory.

In some embodiments of the present disclosure, determining whether the data retention time is available comprises:
determining that the data retention time is unavailable in response to detecting a power-off event during operation of the three-dimensional NAND flash memory; and
determining that the data retention time is available in response to no power-off event being detected during operation of the three-dimensional NAND flash memory.

In some embodiments of the present disclosure, the preset optimal read reference voltage prediction model is constructed using a polynomial fitting method and satisfies the following expression:

V_{avg}(i)−a(i)×pec²+b(i)×[log₂(dr)]²+c(i)×pec×log₂(dr)+d(i)×pec+e(i) ×log₂(dr)+f(i);

wherein a(i), b(i), c(i), d(i), e(i), and f(i) are constants, i denotes an index of the corresponding read reference voltage of the plurality of read reference voltages, V_{avg}(i) denotes the average optimal offset value for the corresponding read reference voltage of the plurality of read reference voltages, pec denotes the program/erase cycle count, and dr denotes the data retention time.

In some embodiments of the present disclosure, estimating the data retention time using the sampling adjustment method comprises:
(S41) sampling a specific read reference voltage at a specific word line in a selected layer of the plurality of layers;
(S42) determining an average optimal offset value for the specific read reference voltage; and
(S43) inputting the average optimal offset value for the specific read reference voltage into the preset optimal read reference voltage prediction model to determine the data retention time.

In some embodiments of the present disclosure, the specific read reference voltage is a read reference voltage that is affected by data retention to a greater extent relative to other read reference voltages at the specific word line in the selected layer of the plurality of layers, and the selected layer is determined based on a sampling ranking table corresponding to the specific read reference voltage.

In some embodiments of the present disclosure, the sampling ranking table records a plurality of layers that are ranked ahead when the layers are sorted, in ascending order, based on differences indicated in the layer-to-layer difference table, wherein the ranking is determined according to how close an optimal offset value of a specific read reference voltage of a given layer is to an average optimal offset value of the specific read reference voltage across the plurality of layers.

In some embodiments of the present disclosure, the layer-to-layer difference table is configured to store, for each layer of the plurality of layers and for each read reference voltage of the plurality of read reference voltages in the layer, a difference between an optimal offset value for the read reference voltage in the layer and an average of all optimal offset values for the read reference voltage in all of the plurality of layers.

In some embodiments of the present disclosure, determining the average optimal offset value for the specific read reference voltage comprises:
(S421) performing a plurality of samplings within a sampling voltage range of the specific read reference voltage using a fixed step size;
(S422) for each sampling of the plurality of samplings, performing read operations and counting a bit flip number;
(S423) obtaining a plurality of fitting points by using the bit flip number as a vertical coordinate of each fitting point of the plurality of fitting points and a midpoint value of a voltage range of each sampling as a horizontal coordinate of each fitting point of the plurality of fitting points;
(S424) performing polynomial fitting on the plurality of fitting points, and determining that a horizontal coordinate corresponding to a fitting point where a derivative is zero is an optimal offset value for the specific read reference voltage;
(S425) averaging optimal offset values of the specific read reference voltage at a plurality of word lines in the plurality of layers to obtain the average optimal offset value for the specific read reference voltage.

In some embodiments of the present disclosure, the sampling ranking table is configured to store layers having smallest absolute differences among the plurality of layers in the layer-to-layer difference table.

In some embodiments of the present disclosure, the optimal read reference voltage value for each read reference voltage of the plurality of read reference voltages of the respective layer of the plurality of layers of the three-dimensional NAND flash memory satisfies the following expression:

V_{final}(i)=V_{avg}(i)+LDT(i, l);

wherein i denotes an index of the corresponding read reference voltage of the plurality of read reference voltages, l denotes an index of the corresponding layer of the plurality of layers, V_{final}(i) denotes a final optimal read reference voltage value of the corresponding layer of the plurality of layers, V_{avg}(i) denotes an average optimal offset value of the corresponding read reference voltage of the plurality of read reference voltages predicted by a model, and LDT(i, l) denotes a difference between an optimal offset value for the corresponding read reference voltage of the plurality of read reference voltages and an average optimal offset value for the corresponding read reference voltage across all of the plurality of layers.

The present disclosure further provides a system for optimizing read reference voltages of a three-dimensional NAND flash memory, comprising:
a reading module, configured to obtain a program/erase cycle count and a data retention time of the three-dimensional NAND flash memory;
a determination module, configured to determine whether the data retention time is available;
a prediction module, configured to, when the data retention time is available, input the program/erase cycle count and the data retention time into a preset optimal read reference voltage prediction model to obtain an average optimal offset value for each read reference voltage of a plurality of read reference voltages;
a sampling adjustment module, configured to, when the data retention time is unavailable, estimate the data retention time using a sampling adjustment method, and input the estimated data retention time and the program/erase cycle count into the preset optimal read reference voltage prediction model to obtain the average optimal offset value for each read reference voltage of the plurality of read reference voltages; and
a compensation module, configured to compensate the average optimal offset values using a layer-to-layer difference table to obtain an optimal read reference voltage value for each read reference voltage of the plurality of read reference voltages of a respective layer of a plurality of layers of the three-dimensional NAND flash memory.

Compared with the prior art, the technical solutions of the present disclosure provide the following beneficial effects.

The present disclosure provides the method and system for optimizing read reference voltages of the three-dimensional NAND flash memory. By constructing the preset optimal read reference voltage prediction model, the optimal read reference voltage value can be rapidly determined and the error rate can be minimized even in the absence of complete and accurate parameters. A sampling adjustment mechanism is further introduced, in which, after power-on, a limited amount of sampling is performed to determine the optimal offset value of the specific read reference voltage and to estimate the data retention time, thereby improving practicality and adaptability of the model. In addition, the sampling ranking table is provided to facilitate selection of representative word lines based on ranking priority for limited sampling, thereby reducing time overhead while maintaining accuracy. Overall, the present disclosure combines model-based prediction with rapid sampling-based optimization to establish a read reference voltage optimization framework applicable to complex scenarios, including multi-layer structures of three-dimensional NAND flash memory and power-off/restart conditions. This approach reduces error correction time and read retry operations, thereby improving read performance of the three-dimensional NAND flash memory.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a diagram illustrating threshold voltage distributions of a triple-level cell (TLC) flash memory in the prior art.

FIG. 2 is a flow chart illustrating a basic process of a flash memory read operation in the prior art.

FIG. 3 is a schematic diagram illustrating overlap of threshold voltage distributions and read reference voltage optimization in the prior art.

FIG. 4 is a flow chart illustrating a method for optimizing read reference voltages of a three-dimensional NAND flash memory according to embodiments of the present disclosure.

FIG. 5 is a schematic diagram illustrating a layer-to-layer difference table according to embodiments of the present disclosure.

FIG. 6 is a schematic diagram illustrating variation of an optimal offset value of a specific read reference voltage after data retention according to embodiments of the present disclosure.

FIG. 7 is a schematic diagram illustrating a sampling adjustment according to embodiments of the present disclosure.

FIG. 8 is a structural block diagram of a system for optimizing read reference voltages of a three-dimensional NAND flash memory according to embodiments of the present disclosure.

### DETAILED DESCRIPTION OF EMBODIMENTS

The accompanying drawings are provided for illustrative purposes only and shall not be construed as limiting the protection range of the present disclosure. For those skilled in the art, it will be understandable that certain well-known features may be omitted from the accompanying drawings for clarity.

For ease of understanding embodiments of the present disclosure, the technical information relevant to the prior art is first described below.

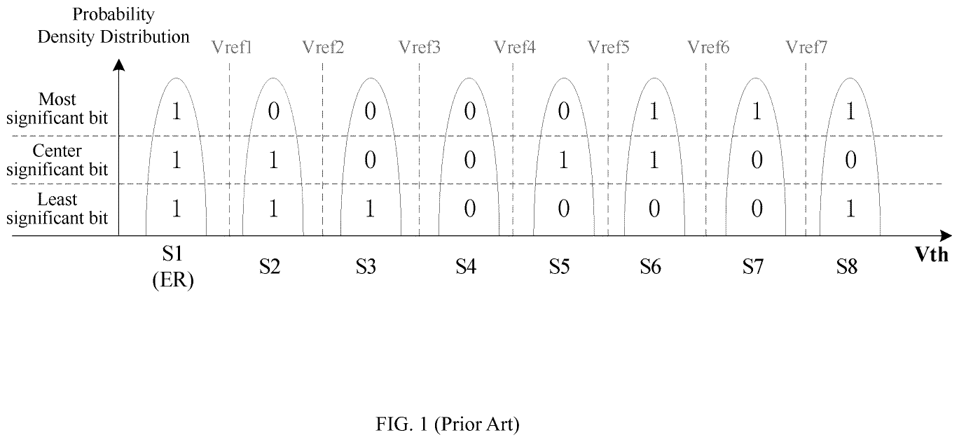

An increase in the number of bits stored per memory cell leads to a corresponding increase in the number of bit combinations (i.e., storage states). In a case where each memory cell stores n bits, a total of 2ⁿ storage states are formed. Accordingly, 2ⁿ⁻¹ read reference voltages (RRV or V_{ref}) are required to distinguish threshold voltage (Vₜₕ) distributions corresponding to storage states. As shown in FIG. 1, a triple-level cell (TLC) flash memory chip includes eight threshold voltage distribution states. To distinguish among these eight states, seven read reference voltages are required. Specifically, V_{ref3} and V_{ref7} are used to distinguish a least significant bit, V_{ref2}, V_{ref4}, and V_{ref6} are used to distinguish a center significant bit, and V_{ref1} and V_{ref5} are used to distinguish a most significant bit. Under desired conditions, the RRVs can be used to completely identify these storage states.

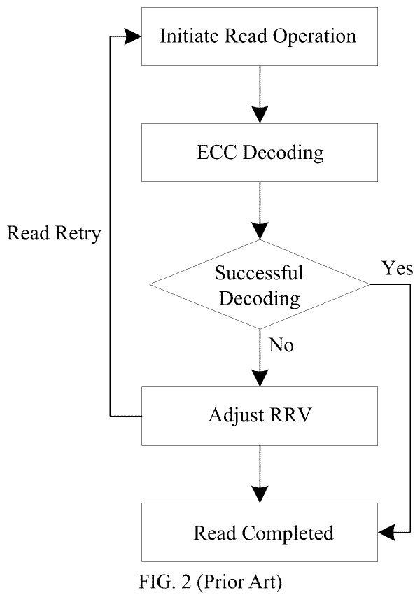

As shown in FIG. 2, to ensure reliability of stored data, flash memory typically employs error correction codes (ECC) to detect and correct errors. However, ECC has limited correction capability. When error correction fails, a read retry mechanism will be triggered.

However, during operation of the flash memory, the raw bit error rate (RBER) increases as the program/erase cycle (PEC) count increases and as the data retention time (DR) becomes longer. In addition, other flash channel noise sources, such as program interference, read disturbance, and physical disturbances, further degrade reliability. As the RBER increases, the time required for ECC decoding and read retry operations to successfully retrieve data correspondingly increases.

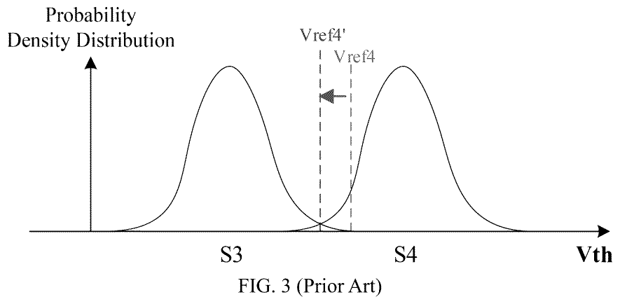

At present, many flash memory devices support adjustment of RRVs through dedicated commands to reduce RBER, thereby reducing ECC latency and the number of read retry operations and improving read performance. As shown in FIG. 3, shifting a read reference voltage V_{ref4} to V_{ref4′}(or a nearby position) can effectively reduce errors caused by Vₜₕ shift and distribution overlap.

Accordingly, efficiently determining an optimal read reference voltage value has become a key research focus in the storage field. Representative categories of existing RRV optimization methods are summarized below.

### (1) Characteristic Modeling Methods

Various approaches based on modeling flash memory characteristics have been proposed.

In a first approach, the Vₜₕ distribution of the flash memory is assumed to approximate a Gaussian distribution. Based on this assumption, prior data is subjected to Gaussian fitting, and statistical parameters of the fitted distributions, including a mean and a variance, are modeled. During application, computations are performed based on parameters input into the model to obtain fitted Gaussian distributions, and an intersection point of the fitted distributions is determined as an optimal read reference voltage value.

A second approach directly models the prior data of the optimal RRVs. During application, the model directly outputs an optimal offset value of the RRV.

A third approach investigates a relationship between optimal RRVs and programming temperature based on prior data, and constructs a model of the relationship. Outputs of the model can be used to optimize RRVs.

Model construction techniques can generally be categorized into polynomial fitting methods and machine learning methods, with polynomial fitting typically providing better interpretability.

### (2) Sampling-Based Optimization Methods

Various sampling-based approaches have been proposed.

A first approach shifts an RRV around a default position and performs read operations, thereby obtaining a number of memory cells falling within a short voltage interval near the default RRV. Based on such sampling data and flash memory characteristics derived from prior data, an optimization direction and magnitude for the RRV can be inferred.

A second approach shifts the RRV across an adjustable voltage range using a predetermined step size and performs read operations. Based on this process, bit flip numbers between successive read operations can be obtained. Polynomial fitting is then performed on the sampling data, and an optimal RRV is determined through mathematical computation.

A third approach investigates a relationship between optimal RRVs and bit flip numbers between two read operations based on prior data, and models the relationship. When a decoding failure occurs during a flash memory read operation, the model output can be used to optimize the RRV. This approach is essentially a sampling-based optimization method incorporating characteristic modeling.

### (3) Asynchronous Estimation Methods

Dual-state asynchronous estimation: a portion of a spare area of each word line is programmed such that a plurality of bytes (e.g., 192 bytes) are respectively programmed into two adjacent storage states (e.g., S3 and S4). When optimization of a RRV is to be performed, read operations are initiated and changes in the storage states of these bytes are determined. Based on the changes, an optimal offset value of a specific RRV within the word line is inferred using a mathematical formulation.

Single-state asynchronous estimation: by further analyzing flash memory characteristics, the above dual-state asynchronous estimation is improved to require only one state (e.g., S4) to infer the optimal RRV, thereby reducing additional storage overhead by approximately 50%.

### (4) Characteristic Layer Methods

Certain approaches identify a “characteristic layer” in a three-dimensional NAND flash memory by analyzing a root mean square error (RMSE) of threshold voltage distributions across different layers, and use an optimal RRV offset value of the characteristic layer to infer optimal RRV offset values of other layers.

### (5) Read Retry Table Modification Methods

Flash memory manufacturers typically provide read retry tables to adjust RRVs when error correction code (ECC) decoding fails. However, recent studies have shown that default read retry tables are not optimal for minimizing the number of read retry operations. Accordingly, some approaches redesign read retry tables or modify an ordering of the read retry table based on flash memory characteristics. By statically or dynamically adjusting the read retry table, the number of read retry operations can be effectively reduced, thereby improving read performance.

### (6) State Equalization Methods

In solid-state drives, a scrambling mechanism is typically employed to randomize data into pseudo-random sequences of zeros and ones before the data is written into the flash memory cells. As a result of such scrambling, the numbers of cells distributed across respective storage states tend to be approximately uniform. Accordingly, the RRV may be progressively adjusted such that the numbers of cells in the respective storage states approach an equal distribution. When the numbers of cells in the respective storage states become substantially equal, the corresponding RRV may be regarded as an optimal read reference voltage value.

### (7) ECC-Assisted Optimization Methods

At present, low density parity check (LDPC) codes are widely used in flash memory. By analyzing relationships between LDPC codes and threshold voltage distributions, the threshold voltage distributions can be estimated, and RRVs can be optimized accordingly.

The present disclosure exhibits characteristics of both characteristic modeling methods and sampling-based optimization methods, while differing from any specific existing solution within these categories. Compared with other approaches, the present disclosure adopts a substantially different approach in both concept and process.

The technical solutions of the present disclosure will be further described below in conjunction with the accompanying drawings and the embodiments.

### Embodiment 1

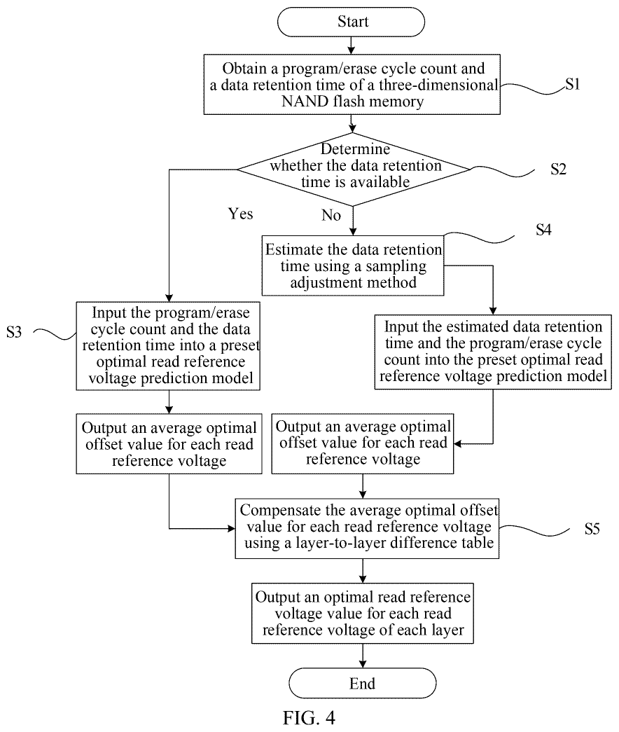

As shown in FIG. 4, this embodiment provides a method for optimizing read reference voltages of a three-dimensional NAND flash memory, and the method includes the following steps.

(S1) A program/erase cycle count and a data retention time of the three-dimensional NAND flash memory are obtained.

(S2) It is determined whether the data retention time is available. In response to determining that the data retention time is available, step S3 is performed. In response to determining that the data retention time is unavailable, step S4 is performed.

At step S2, one manner of obtaining an available data retention time is based on controller-side system logs. Specifically, when a page or block is written, the controller records a current timestamp in metadata or a maintained log. During a subsequent read or refresh operation, the data retention time is determined based on a difference between a current system time and the recorded timestamp. However, if a power-off event occurs during the interval, accuracy of the data retention time may be compromised, and the data retention time is treated as unavailable.

(S3) The program/erase cycle count and the data retention time are input into a preset optimal read reference voltage prediction model to obtain an average optimal offset value for each read reference voltage of a plurality of read reference voltages, and the method proceeds to step S5.

At step S3, based on prior flash memory testing, an optimal offset of a read reference voltage generally increases in a logarithmic manner with increasing data retention time. Accordingly, the data retention time is expressed in logarithmic form during model construction. In addition, the data retention time in the prediction model corresponds to an equivalent retention time at 40 °C. The prediction model constructed using polynomial fitting is expressed as:

V_{avg}(i)=a(i)×pec²+b(i)×[log₂(dr)]²+c(i)×pec×log₂(dr)+d(i)×pec+e(i) ×log₂(dr)+f(i);

where a(i), b(i), c(i), d(i), e(i), and f(i) are constants, i denotes an index of the corresponding read reference voltage of the plurality of read reference voltages, V_{avg}(i) denotes the average optimal offset value for the corresponding read reference voltage of the plurality of read reference voltages, pec denotes the program/erase cycle count, and dr denotes the data retention time.

(S4) The data retention time is estimated using a sampling adjustment method, the estimated data retention time and the program/erase cycle count are input into the preset optimal read reference voltage prediction model to obtain the average optimal offset value for each read reference voltage of the plurality of read reference voltages, and the method proceeds to step S5.

At step S4, the data retention time is estimated using the sampling adjustment method as follows.
(S41) A specific read reference voltage at a specific word line in a selected layer of the plurality of layers is sampled.
(S42) An average optimal offset value for the specific read reference voltage is determined.
(S43) The average optimal offset value for the specific read reference voltage is input into the preset optimal read reference voltage prediction model to determine the data retention time.

(S5) The average optimal offset value for each read reference voltage of the plurality of read reference voltages is compensated using a layer-to-layer difference table to obtain an optimal offset value for each read reference voltage of the plurality of read reference voltages of a respective layer of a plurality of layers of the three-dimensional NAND flash memory.

At step S5, the optimal read reference voltage value for each layer satisfies the following expression:

V_{final}(i)=V_{avg}(i)+LDT(i, l);

where i denotes an index of the corresponding read reference voltage of the plurality of read reference voltages, l denotes an index of the corresponding layer of the plurality of layers, V_{final}(i) denotes a final optimal read reference voltage value of the corresponding layer of the plurality of layers, V_{avg}(i) denotes an average optimal offset value of the corresponding read reference voltage of the plurality of read reference voltages predicted by a model, and LDT(i, l) denotes a difference between an optimal offset value for the corresponding read reference voltage of the plurality of read reference voltages and an average optimal offset value for the corresponding read reference voltage across all of the plurality of layers.

Through steps S1 to S4, the read reference voltages can be adjusted to be closer to current optimal read reference voltages, such that decision errors caused by overlap of threshold voltage distributions are reduced and a number of errors in a read bitstream is lowered. As a result, subsequent ECC processing is more likely to successfully complete hard decoding in a single attempt, thereby reducing a probability of invoking soft decoding or triggering a read retry operation. Since soft decoding or read retry incurs significantly higher latency than hard decoding, the steps of the present disclosure can reduce time overhead associated with read operations.

In this embodiment, compared with modeling approaches that require complete parameter inputs, the present disclosure allows recovery of model inputs through sampling when parameters are unavailable. Compared with conventional full-range multi-point sampling approaches, the present disclosure employs a sampling ranking strategy such that a limited number of sampling operations are sufficient to predict optimal read reference voltage values. By combining model-based prediction with sampling-based adjustment, the overall scheme of the present disclosure is applicable to scenarios including power-off/restart conditions and multi-layer structures, thereby reducing error rates and read retry operations and improving read performance of the flash memory.

### Embodiment 2

Step S4 is further described in detail as follows.

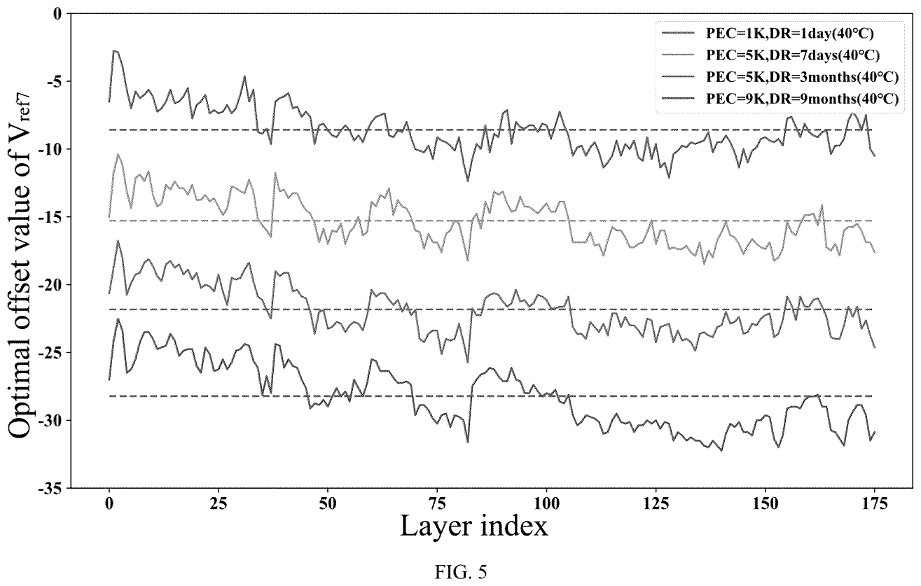

At step S41, different storage states exhibit different degrees of shift in their threshold voltage distributions after being subjected to flash channel noise. After a long data retention time, some states may experience a large shift, thereby causing a corresponding substantial shift in an optimal position of a read reference voltage used to distinguish these states. Accordingly, the specific read reference voltage is a read reference voltage that is affected by data retention to a greater extent relative to other read reference voltages at the specific word line in the selected layer of the plurality of layers. Further, since word lines within a same layer exhibit similarity, the specific word line is a word line randomly chosen from each sampled layer. In addition, in a three-dimensional NAND flash memory, differences among optimal RRV offset values across layers exhibit a general stability in magnitude. Therefore, the layer-to-layer difference table may be obtained by processing chip test results. The layer-to-layer difference table is configured to store, for each layer of the plurality of layers and for each read reference voltage of the plurality of read reference voltages in the layer, a difference between an optimal offset value for the read reference voltage in the layer and an average of all optimal offset values for the read reference voltage in all of the plurality of layers. Such inter-layer stability indicates that, when an average optimal offset value at a current time is obtained, all RRVs of all layers may be optimized using the layer-to-layer difference table. A schematic line chart of the layer-to-layer difference table is shown in FIG. 5, which illustrates that such stability may become partially non-uniform due to complex interference conditions during flash operation. Accordingly, absolute values of the differences are taken and sorted in ascending order. A higher ranking indicates that the optimal offset value for the read reference voltage in a corresponding layer is closer to the average optimal offset value across all layers. A plurality of top-ranked layers are recorded to form a sampling ranking table. Sampling operations are then sequentially performed on word lines from the selected layers according to the sampling ranking table. It should be noted that, for different read reference voltages, ranking results of layers may differ. Since sampling is performed on a read reference voltage that is affected by data retention to a greater extent relative to other read reference voltages at the specific word line in the selected layer of the plurality of layers, only a sampling ranking table corresponding to the specific read reference voltage is required to be recorded.

Step S42 may include the following steps.

(S421) A plurality of samplings are performed within a sampling voltag range of the specific read reference voltage using a fixed step size.

(S422) For each sampling of the plurality of samplings, read operations are performed and a bit flip number is counted.

(S423) A plurality of fitting points are obtained by using the bit flip number as a vertical coordinate of each fitting point of the plurality of fitting points and a midpoint value of a voltage range of each sampling as a horizontal coordinate of each fitting point of the plurality of fitting points.

(S424) Polynomial fitting is performed on the plurality of fitting points, and a horizontal coordinate, corresponding to a fitting point where a derivative is zero, is determined as an optimal offset value for the specific read reference voltage.

(S425) Optimal offset values of the specific read reference voltage at a plurality of word lines in the plurality of layers are averaged to obtain the average optimal offset value for the specific read reference voltage.

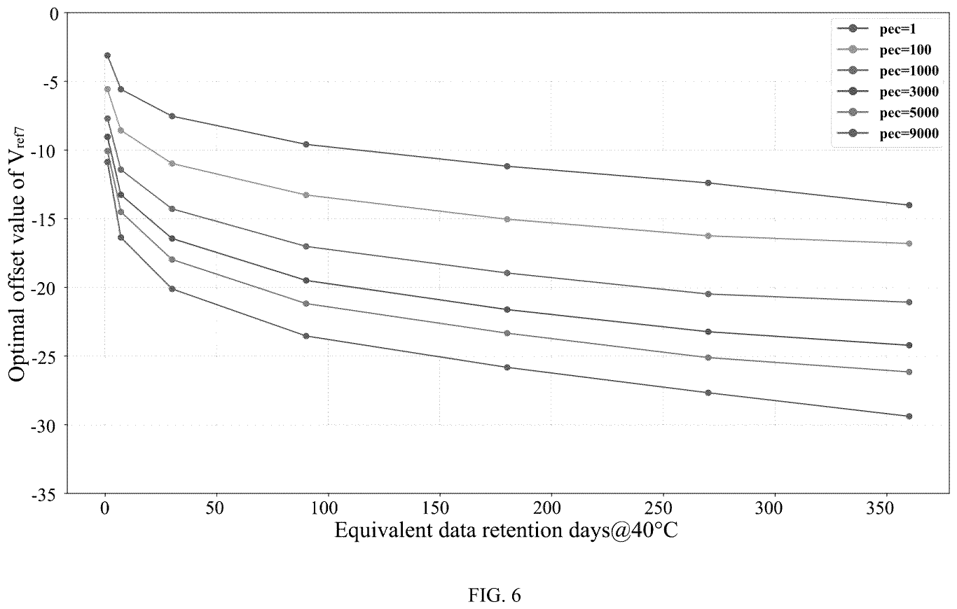

At step S421, the step size refers to a minimum adjustable voltage level of the flash memory chip. The sampling voltage range is determined based on an output of the preset optimal read reference voltage prediction model when an accurate data retention time is unavailable (for example, after a power-off event). A left boundary of the sampling voltage range may be determined as follows. It may be generally assumed that, after a power-off event, the device is stored under ambient temperature below 40 °C. A higher temperature leads to a more severe negative shift, and thus a model output is generally located on a left side of an actual optimal RRV. Although the device may be exposed to a higher temperature environment for a certain period, the influence of data retention time on the sampled RRV increases logarithmically, as shown in FIG. 6. Accordingly, subtracting a predetermined number of step sizes (e.g., 20 steps) from the model output is sufficient to determine the left boundary. A right boundary of the sampling voltage range may be determined as follows. As shown in FIG. 6, during data retention, the specific read reference voltage shifts in a negative direction. Therefore, the right boundary of the sampling voltage range may be set offset from a default value of the specific read reference voltage by a predetermined number of step sizes (e.g., 10 steps) toward a positive direction. After determining the step size and the left and right boundaries, sampling operations are performed sequentially on word lines from selected layers according to the sampling ranking table. For each sampled layer, sampling is performed from the left boundary across the sampling voltage range at intervals of the step size.

At step S422, the specific read reference voltage is adjusted to corresponding sampling positions and read operations are performed. Results of adjacent read operations are compared to obtain the bit flip number.

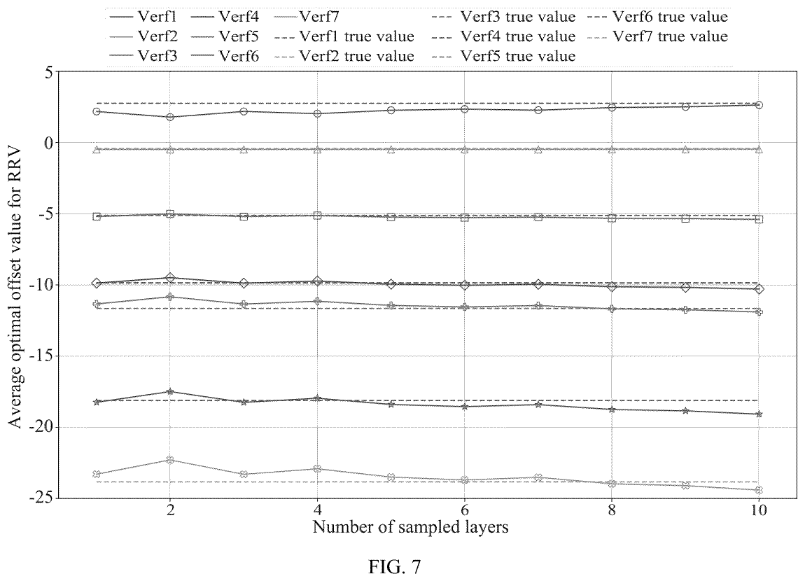

At step S425, the estimated data retention time and the program/erase cycle count are input into prediction models corresponding to other read reference voltages to obtain average optimal offset values for the other read reference voltages, thereby obtaining average optimal offset values for all read reference voltages. An example of a sampling adjustment effect is shown in FIG. 7.

Conventional optimization strategies typically require repeated sampling and fitting across multiple layers and multiple RRVs within a relatively wide voltage range, resulting in high time consumption. In contrast, at step S4, the present disclosure selects only a specific read reference voltage that is affected by data retention time to a greater extent relative to other read reference voltages, and determines an average optimal offset value of the specific read reference voltage through limited sampling based on a selected layer and a specific word line (see steps S41 and S42). The average optimal offset value is then input into the preset optimal read reference voltage prediction model to estimate the data retention time (step S43). In this manner, a limited amount of sampling is used to recover a missing parameter required by the preset optimal read reference voltage prediction model, thereby avoiding sampling across all layers and all read reference voltages over a full voltage range. Accordingly, time overhead introduced by the RRV optimization scheme of the present disclosure is significantly lower than that of conventional full-sampling approaches.

Step S5 converts the average optimal offset value for each read reference voltage into an optimal read reference voltage for each read reference voltage of a respective layer, thereby further reducing a raw bit error rate and decreasing read retry operations. Specifically, at step S5, the average optimal offset value Vavg(i) is compensated using a layer-to-layer difference table to obtain, for each read reference voltage of each layer, an optimal read reference voltage V_{final}(i)=V_{avg}(i)+LDT(i, l). Through step S5, inter-layer differences of a three-dimensional NAND flash memory are incorporated into RRV configuration, such that a controller can update corresponding V_{ref}/read retry register parameters on a per-layer basis prior to initiating an actual read operation, thereby avoiding increased raw bit error rates in certain layers caused by applying uniform read reference voltages across all layers.

Taken together, improvements in read performance achieved by steps S1 S5 may be summarized as follows: accurately determining optimal read reference voltages on a per-layer basis to reduce a raw bit error rate, and reducing optimization time overhead by replacing large-scale sampling with model-based prediction combined with limited sampling, thereby reducing triggering of soft decoding and read retry operations and reducing read latency.

### Embodiment 3

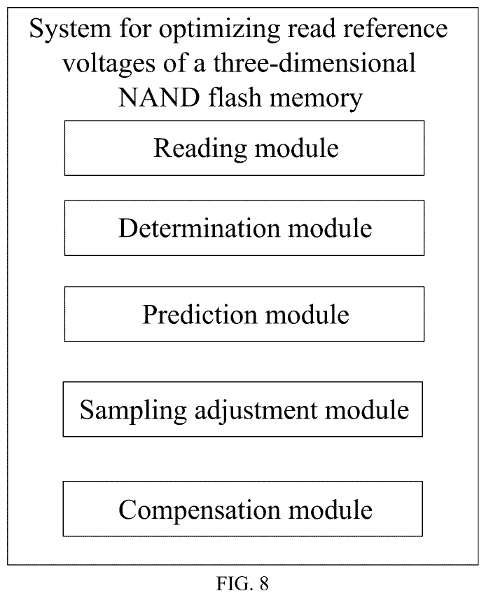

Referring to FIG. 8, the present embodiment provides a system for optimizing read reference voltages of a three-dimensional NAND flash memory. The system includes a reading module, a determination module, a prediction module, a sampling adjustment module, and a compensation module. The reading module is configured to obtain a program/erase cycle count and a data retention time of the three-dimensional NAND flash memory. The determination module is configured to determine whether the data retention time is available. The prediction module is configured to, when the data retention time is available, input the program/erase cycle count and the data retention time into a preset optimal read reference voltage prediction model to obtain an average optimal offset value for each read reference voltage of a plurality of read reference voltages. The sampling adjustment module is configured to, when the data retention time is unavailable, estimate the data retention time using a sampling adjustment method, and input the estimated data retention time and the program/erase cycle count into the preset optimal read reference voltage prediction model to obtain the average optimal offset value for each read reference voltage of the plurality of read reference voltages. The compensation module is configured to compensate the average optimal offset values using a layer-to-layer difference table to obtain an optimal read reference voltage value for each read reference voltage of the plurality of read reference voltages of a respective layer of a plurality of layers of the three-dimensional NAND flash memory.

During implementation, the technical solutions of the present disclosure may involve coordinated operation of multiple types of hardware components, including a three-dimensional NAND flash memory chip, a flash memory controller, and storage and computation resources on a controller side. The three-dimensional NAND flash memory chip may include a memory cell array with corresponding threshold voltage distributions, as well as voltage control circuitry and associated register interfaces configured to set read reference voltages. The flash memory controller may include a processor core, an error correction code engine, read retry control logic, and firmware execution components. In addition, on-chip or external memory (e.g., SRAM or DRAM) may be provided to store data such as program/erase cycle count, timestamp information, the layer-to-layer difference table, and the sampling ranking table. The above hardware components may communicate commands and data through standard flash interfaces (e.g., ONFI or Toggle interface) to support execution of the method of the present disclosure.

During implementation, the flash memory controller may obtain the program/erase cycle count and related timing information via an internal counting module and a logging module, and determine, at the controller side, whether the data retention time is available. When the data retention time is available, the controller may execute the preset optimal read reference voltage prediction model to obtain an average optimal offset value for each read reference voltage. When the data retention time is unavailable, the controller may issue control instructions to the NAND flash memory chip via an interface to perform a sampling process on a specific read reference voltage at a specific word line in a selected layer. The sampling process may include multiple iterations of “setting a reference voltage and initiating a read operation.” During this process, the controller may write to an RRV register to adjust the read reference voltage and trigger read commands, and the NAND flash memory chip may return corresponding bit data. The controller may further compare results of adjacent read operations to obtain a bit flip number, and perform fitting computations based on sampling data at the controller side to obtain parameters for estimating the data retention time. Accordingly, a multi-round interaction between the controller and the NAND flash memory chip is established, including voltage setting, read operation triggering, and data return and processing.

After obtaining the average optimal offset value for each read reference voltage, the controller may further access the layer-to-layer difference table stored in a local storage unit to perform layer-wise compensation on the offset values, thereby obtaining a final read reference voltage for each layer. Subsequently, during an actual read operation, the controller may, prior to initiating the read operation, write corresponding final read reference voltages into an RRV control register or a voltage control interface of the NAND flash memory chip according to a currently accessed layer index, such that the chip performs the read operation using the updated read reference voltage. At this stage, threshold voltages of memory cells are compared with the read reference voltages to generate bit data, which is returned to the controller for subsequent decoding by the ECC engine.

Through the above hardware interaction, the present disclosure provides a regulation mechanism in which controller-side computation cooperates with voltage execution at the flash memory chip side. On one hand, by dynamically adjusting the read reference voltage to more closely match decision boundaries corresponding to a current threshold voltage distribution, decision errors caused by distribution overlap are reduced, thereby lowering the raw bit error rate and enabling more read operations to be completed at an ECC hard-decoding stage. On the other hand, by combining model-based computation with limited sampling, the number of read operations required for determining read reference voltages is reduced, thereby decreasing additional time overhead. These effects are reflected at the hardware level as a reduction in read operation count, improved voltage setting accuracy, and shortened error correction processing paths, thereby reducing overall read latency and improving read performance of the storage system.

It should be apparent that the above embodiments of the present disclosure are provided for purposes of illustration only and are not intended to limit the scope of the present disclosure. For a person skilled in the art, various modifications and variations may be made based on the above disclosure without departing from the spirit and principles of the present disclosure. Such modifications, equivalent substitutions, and improvements shall fall within the scope of protection defined by the claims of the present disclosure.

What is claimed is:

1. A method for optimizing read reference voltages of a three-dimensional NAND flash memory, the method comprising:
(S1) obtaining a program/erase cycle count and a data retention time of the three-dimensional NAND flash memory;
(S2) determining whether the data retention time is available;
(S3) in response to determining that the data retention time is available, inputting the program/erase cycle count and the data retention time into a preset optimal read reference voltage prediction model to obtain an average optimal offset value for each read reference voltage of a plurality of read reference voltages;
(S4) in response to determining that the data retention time is unavailable, estimating the data retention time using a sampling adjustment method, and inputting the estimated data retention time and the program/erase cycle count into the preset optimal read reference voltage prediction model to obtain the average optimal offset value for each read reference voltage of the plurality of read reference voltages; and
(S5) compensating the average optimal offset value for each read reference voltage of the plurality of read reference voltages using a layer-to-layer difference table to obtain an optimal read reference voltage value for each read reference voltage of the plurality of read reference voltages of a respective layer of a plurality of layers of the three-dimensional NAND flash memory.

2. The method of claim 1, wherein determining whether the data retention time is available comprises:
determining that the data retention time is unavailable in response to detecting a power-off event during operation of the three-dimensional NAND flash memory; and
determining that the data retention time is available in response to no power-off event being detected during operation of the three-dimensional NAND flash memory.

3. The method of claim 1, wherein the preset optimal read reference voltage prediction model is constructed using a polynomial fitting method and satisfies the following expression:
V_{avg}(i)=a(i)×pec²+b(i)×[log₂(dr)]²+c(i)×pec×log₂(dr)+d(i)×pec+e(i) ×log₂(dr)+f(i);
wherein a(i), b(i), c(i), d(i), e(i), and f(i) are constants, i denotes an index of the corresponding read reference voltage of the plurality of read reference voltages, V_{avg}(i) denotes the average optimal offset value for the corresponding read reference voltage of the plurality of read reference voltages, pec denotes the program/erase cycle count, and dr denotes the data retention time.

4. The method of claim 1, wherein estimating the data retention time using the sampling adjustment method comprises:
(S41) sampling a specific read reference voltage at a specific word line in a selected layer of the plurality of layers;
(S42) determining an average optimal offset value for the specific read reference voltage; and
(S43) inputting the average optimal offset value for the specific read reference voltage into the preset optimal read reference voltage prediction model to determine the data retention time.

5. The method of claim 4, wherein the specific read reference voltage is a read reference voltage that is affected by data retention to a greater extent relative to other read reference voltages at the specific word line in the selected layer of the plurality of layers, and the selected layer is determined based on a sampling ranking table corresponding to the specific read reference voltage.

6. The method of claim 4, wherein the layer-to-layer difference table is configured to store, for each layer of the plurality of layers and for each read reference voltage of the plurality of read reference voltages in the layer, a difference between an optimal offset value for the read reference voltage in the layer and an average of all optimal offset values for the read reference voltage in all of the plurality of layers.

7. The method of claim 4, wherein determining the average optimal offset value for the specific read reference voltage comprises:
(S421) performing a plurality of samplings within a sampling voltage range of the specific read reference voltage using a fixed step size;
(S422) for each sampling of the plurality of samplings, performing read operations and counting a bit flip number;
(S423) obtaining a plurality of fitting points by using the bit flip number as a vertical coordinate of each fitting point of the plurality of fitting points and a midpoint value of a voltage range of each sampling as a horizontal coordinate of each fitting point of the plurality of fitting points;
(S424) performing polynomial fitting on the plurality of fitting points, and determining that a horizontal coordinate corresponding to a fitting point where a derivative is zero is an optimal offset value for the specific read reference voltage;
(S425) averaging optimal offset values of the specific read reference voltage at a plurality of word lines in the plurality of layers to obtain the average optimal offset value for the specific read reference voltage.

8. The method of claim 5, wherein the sampling ranking table is configured to store layers having smallest absolute differences among the plurality of layers in the layer-to-layer difference table.

9. The method of claim 1, wherein the optimal read reference voltage value for each read reference voltage of the plurality of read reference voltages of the respective layer of the plurality of layers of the three-dimensional NAND flash memory satisfies the following expression:
V_{final}(i)=V_{avg}(i)+LDT(i, l);
wherein i denotes an index of the corresponding read reference voltage of the plurality of read reference voltages, l denotes an index of the corresponding layer of the plurality of layers, V_{final}(i) denotes a final optimal read reference voltage value of the corresponding layer of the plurality of layers, V_{avg}(i) denotes an average optimal offset value of the corresponding read reference voltage of the plurality of read reference voltages predicted by a model, and LDT(i, l) denotes a difference between an optimal offset value for the corresponding read reference voltage of the plurality of read reference voltages and an average optimal offset value for the corresponding read reference voltage across all of the plurality of layers.

10. A system for optimizing read reference voltages of a three-dimensional NAND flash memory, comprising:
a reading module, configured to obtain a program/erase cycle count and a data retention time of the three-dimensional NAND flash memory;
a determination module, configured to determine whether the data retention time is available;
a prediction module, configured to, when the data retention time is available, input the program/erase cycle count and the data retention time into a preset optimal read reference voltage prediction model to obtain an average optimal offset value for each read reference voltage of a plurality of read reference voltages;
a sampling adjustment module, configured to, when the data retention time is unavailable, estimate the data retention time using a sampling adjustment method, and input the estimated data retention time and the program/erase cycle count into the preset optimal read reference voltage prediction model to obtain the average optimal offset value for each read reference voltage of the plurality of read reference voltages; and
a compensation module, configured to compensate the average optimal offset values using a layer-to-layer difference table to obtain an optimal read reference voltage value for each read reference voltage of the plurality of read reference voltages of a respective layer of a plurality of layers of the three-dimensional NAND flash memory.
